(19) United States
(12) Patent Application Publication
(10) Pub. No.: US 2021/0083128 A1
(43) Pub. Date: Mar. 18, 2021

(54) SEMICONDUCTOR DEVICE AND MANUFACTURING METHOD THEREOF

(71) Applicant: KIOXIA CORPORATION, Tokyo (JP)

(72) Inventors: Masaki NOGUCHI, Yokkaichi Mie (JP); Tatsunori ISOGAI, Yokkaichi Mie (JP); Shunsuke OKADA, Suzuka Mie (JP)

(21) Appl. No.: 16/805,282

(22) Filed: Feb. 28, 2020

(30) Foreign Application Priority Data
Sep. 13, 2019 (JP) 2019-167157

(51) Int. Cl. H01L 29/792; H01L 27/11582; H01L 29/51; H01L 21/28; H01L 29/66

(52) U.S. Cl. CPC H01L 29/7926; H01L 27/11582; H01L 29/66833; H01L 29/40117; H01L 29/513

(57) ABSTRACT

A method of manufacturing a semiconductor device includes forming a stacked body including a plurality of first films and a plurality of second films that are alternately stacked, next forming, in the stacked body, an opening that extends in a thickness direction, then forming a first insulating film, a charge storage layer, a second insulating film, and a semiconductor layer on a side wall of the stacked body in the opening. The charge storage layer includes a silicon nitride film. The second insulating film includes a silicon oxynitride film. At least one of the silicon nitride film and the silicon oxynitride film is formed by using first gas containing silicon and second gas containing nitrogen and deuterium.

### CROSS-REFERENCE TO RELATED APPLICATION(S)

This application is based upon and claims the benefit of priority from Japanese Patent Application No. 2019-167157, filed on Sep. 13, 2019, the entire contents of which are incorporated herein by reference.

### FIELD

Embodiments described herein relate generally to a semiconductor device and a manufacturing method thereof.

### BACKGROUND

A semiconductor memory of one type includes a three-dimensional memory cell array in which a plurality of memory cells are three-dimensionally arranged. When the three-dimensional memory cell array is manufactured, a tunnel insulating film and a charge storage layer are deposited to be used in a memory cell to store data.

However, when write and erase operations are repeatedly performed in such a device, a defect may eventually form in the tunnel insulating film and the charge storage layer, and thus stored data may be lost.

### DESCRIPTION OF THE DRAWINGS

FIG. 1 depicts a semiconductor device according to a first embodiment.

FIGS. 2A and 2B are cross-sectional views for illustrating aspects of a manufacturing method of a semiconductor device according to a first embodiment.

FIG. 3 is a flowchart for illustrating aspects related to a manufacturing method of a silicon nitride film according to a first embodiment.

FIG. 4 is a graph illustrating concentration profile of hydrogen H in a silicon nitride film.

FIG. 5 is a flowchart for illustrating aspects related to a manufacturing method of a silicon oxynitride film according to the first embodiment.

FIG. 6 is a graph illustrating a concentration profile of hydrogen H in a silicon oxynitride film.

FIG. 7 is a flowchart illustrating a manufacturing method of a silicon nitride film in a semiconductor device according to a second embodiment.

FIG. 8 is a flowchart for illustrating aspects related to a manufacturing method of a silicon oxynitride film in a semiconductor device according to a second embodiment.

### DETAILED DESCRIPTION

Certain example embodiments are directed to preventing deterioration of a tunnel insulating film and a charge storage layer in a semiconductor device, and a related manufacturing method.

In general, according to an embodiment, a method of manufacturing a semiconductor device includes forming a stacked body including a plurality of first films and a plurality of second films, forming, in the stacked body, an opening that extends in a thickness direction of the stacked body, and then forming a first insulating film, a charge storage layer, a second insulating film, and a semiconductor layer on a side wall of the stacked body in the opening. The charge storage layer includes a silicon nitride film. The second insulating film includes a silicon oxynitride film. At least one of the silicon nitride film and the silicon oxynitride film is formed by using a first gas containing silicon and a second gas containing nitrogen and deuterium.

Hereinafter, certain example embodiments according to the present disclosure will be described with reference to the drawings. These example embodiments do not limit the present disclosure. In general, the drawings are schematic and/or conceptual, and as such the ratio(s) in dimensions/sized of each depicted element/component/aspect in the drawings is not necessarily the same as would be utilized in an actual implementation of the present disclosure. In the specification and the drawings, those components, elements, or aspects that are substantially similar to those in other drawings and/or embodiments will be denoted by the same reference signs, and the repeated description of such components, elements, or aspects may be omitted in some instances.

### First Embodiment

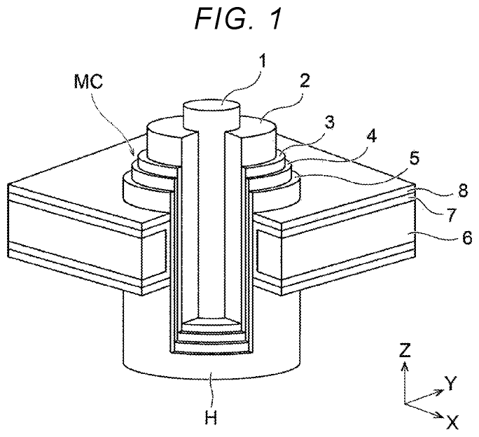

FIG. 1 illustrates a perspective view of a semiconductor device according to a first embodiment. The semiconductor device according to the first embodiment is, for example, a semiconductor memory including a three-dimensional memory cell array in which a plurality of memory cells are three-dimensionally disposed.

The semiconductor device in FIG. 1 includes a core insulating film 1, a semiconductor channel layer 2, a tunnel insulating film 3, a charge storage layer 4, a block insulating film 5, a wiring layer 6, a first metal layer 7, and a second metal layer 8. The wiring layer 6, the block insulating film 5, the tunnel insulating film 3, and the semiconductor channel layer 2 are examples of a conductive layer, a first insulating film, a second insulating film, and a semiconductor layer, respectively.

Although not specifically illustrated in FIG. 1, a plurality of wiring layers and a plurality of insulating layers are alternately stacked on a substrate, and a memory hole H is provided passing through these wiring layers and insulating layers. FIG. 1 shows an X direction and a Y direction parallel to a surface of the wiring layer 6 and perpendicular to each other, and a Z direction perpendicular to the surface of the wiring layer 6. In the specification, a +Z direction is defined as an upward direction, and a −Z direction is defined as a downward direction. The −Z direction may coincide with a gravity direction or may not coincide with the gravity direction. As illustrated in FIG. 1, there is a wiring layer 6, a first metal layer 7, and a second metal layer 8 stacked on each other. This stack may be collectively referred to as a “wiring layer” in some instances. In the semiconductor device each of these wiring layers functions as a gate electrode (which may be considered a word line wiring in some examples), and each insulating layer between adjacent wiring layers functions as an element isolation insulating film.

The core insulating film 1, the semiconductor channel layer 2, the tunnel insulating film 3, the charge storage layer 4, and the block insulating film 5 are formed in the memory hole H, and collectively form a memory cell MC. Specifically, the block insulating film 5 has, for example, a cylindrical shape, and is formed in the memory hole H on the wiring layer and a side wall of the insulating layer. The charge storage layer 4 also has, for example, a cylindrical shape, and is formed on an inner surface of the block insulating film 5. The tunnel insulating film 3 also has, for example, a cylindrical shape, and is formed on an inner surface of the charge storage layer 4. The semiconductor channel layer 2 also has, for example, a cylindrical shape, and is formed on an inner surface of the tunnel insulating film 3. The core insulating film 1 has, for example, a columnar shape, and is filled in the semiconductor channel layer 2.

An example of the block insulating film 5 includes an aluminum oxide film (Al₂O₃) and a silicon oxide film (SiO₂). An example of the charge storage layer 4 is a silicon nitride film (SiN). An example of the tunnel insulating film 3 is a stacked film including a first silicon oxide film, a silicon oxynitride film (SiON), and a second silicon oxide film. An example of the semiconductor channel layer 2 is a silicon layer. An example of the core insulating film 1 is a silicon oxide film. Examples of the wiring layer 6, the first metal layer 7, and the second metal layer 8 are a tungsten layer (W), a titanium nitride film (TiN), and an aluminum oxide film, respectively. In this case, the first metal layer 7 functions as a barrier metal layer, and the second metal layer 8 is an insulating metal and functions as a block insulating film together with the block insulating film 5.

A memory cell MC comprises a cell insulating film, such as the block insulating film 5, the charge storage layer 4, and the tunnel insulating film 3, the semiconductor channel layer 2, and the core insulating film. The memory cell MC is provided corresponding to an intersection point of the wiring layer 6 and the memory hole H. In FIG. 1, a single memory cell MC is illustrated. In a three-dimensional semiconductor memory including the above-described structure, a write operation is performed by injecting an electron into the charge storage layer via the channel film and the tunnel insulating film, and an erase operation is performed by injecting a positive hole and neutralizing the previously captured/stored electron.

In a charge trap memory, when the write and erase operation is repeatedly performed, a defect can be generated in the charge storage layer 4 and the tunnel insulating film 3, such that a part of the charges stored in the charge storage layer 4 is removed via the defect. This causes data loss. The defect in the charge storage layer 4 and the tunnel insulating film 3 is considered to occur when hydrogen (H), introduced intentionally or unintentionally at the time of forming the memory cell, is desorbed by electrical stress caused by the write and erase operation.

To address such issues, in the present embodiment, it is considered that deuterium (D) (also known as heavy hydrogen, hydrogen-2, ²H, or the like) is introduced into the silicon nitride film (SiN film) or the silicon oxynitride film (SiON film) used for the charge storage layer 4 and the tunnel insulating film 3. When hydrogen concentration of the silicon nitride film or the silicon oxynitride film is reduced and deuterium is introduced, an N—H bond in the silicon nitride film or the silicon oxynitride film can be replaced with an N-D bond. The N-D bond is significantly higher in electrical stress resistance than the N—H bond. Therefore, when the number of N—H bonds in the charge storage layer 4 and the tunnel insulating film 3 can be reduced and the number of N-D bonds can be increased, the deterioration of the charge storage layer 4 and the tunnel insulating film 3 caused by the write and erase operation can be reduced.

However, in order to replace the hydrogen already contained in a silicon nitride film or a silicon oxynitride film with deuterium, generally a high-temperature heat treatment of about 800° C. or higher is required with the sample being in an atmosphere rich in deuterium (D) or heavy water (D₂O). However, the influence of heat on a peripheral circuit of a semiconductor device is typically large, and by such heating a characteristic of the peripheral circuit may be changed. For that reason, it is desirable to reduce the hydrogen concentration in the charge storage layer 4 and the tunnel insulating film 3 and to increase deuterium concentration in a manner that does to significantly affect the peripheral circuit.

Here, the charge storage layer 4 and the tunnel insulating film 3 are assumed to be a silicon nitride film and a silicon oxynitride film, respectively, and the component concentrations thereof will be described.

Nitrogen concentration with respect to silicon and oxygen in the silicon oxynitride film is in a range of 10 at % to 30 at %. The silicon nitride film or the silicon oxynitride film contains hydrogen (H), and the hydrogen concentration in the silicon nitride film or the silicon oxynitride film is 1×10¹⁹ [atoms/cm³] or lower. That is, an N—H bond amount and a Si—H bond amount in the silicon nitride film or the silicon oxynitride film are 1×10¹⁹ [pieces/cm³] or lower.

In order to perform the write and erase operation at a low voltage, it is effective to change a material for forming the tunnel insulating film 3 to a material having a small band gap or to narrow the band gap of the silicon oxynitride film in the tunnel insulating film 3. When the nitrogen concentration in the silicon oxynitride film is increased, a barrier height on the positive hole side with respect to silicon is significantly reduced, thereby making it possible to greatly reduce an erase operation voltage.

However, as the nitrogen concentration in the silicon oxynitride film increases, a structure of the silicon oxynitride film changes to a structure in which the electron and the positive hole are easily trapped. In this case, the charge in the charge storage layer 4 may be removed from the tunnel insulating film 3 and thus a charge storage characteristic may deteriorate, and insulating performance of the tunnel insulating film 3 itself may deteriorate, thereby causing a problem of deterioration in reliability. For example, erroneous writing is performed on a cell adjacent to a desired cell at the time of writing or reading, thereby causing a problem that reliability of a cell operation deteriorates. To address such issues, according to the embodiment, the nitrogen concentration in the silicon oxynitride film is set to 10 to 30 at % as described above. Accordingly, it is possible to control charge trap to the silicon oxynitride film while narrowing the band gap of the silicon oxynitride film.

It is known that the N—H bond amount in the silicon oxynitride film will be increased by the increase in the nitrogen concentration. It is considered that the N—H bond has low bonding energy and is typically dissociated by a thermal load in a post-process, and the moiety —N* formed by the dissociation becomes a trap site for capturing charge. In this context, the symbol * indicates a dangling bond or unreacted bonding site. When manufacturing a three-dimensional flash memory, it is required to form a high-quality tunnel insulating film 3 in a memory hole H having a high aspect ratio, so that it is usually desirable to form the silicon oxynitride film by an atomic layer deposition (ALD) method. However, when the silicon oxynitride film is formed by the ALD method, ammonia (NH₃) is often used as a nitriding agent. In this case, moieties —Si and —N* in the silicon oxynitride film are generally hydrogen-terminated so as to form Si—H bonds and N—H bonds. These can become trap sites for capturing both electrons and positive holes once the bonded hydrogen becomes dissociated (as occurs after repeated write/erase cycles). That is, it is considered that a trap amount of the charge to the tunnel insulating film 3 increases as the hydrogen concentration in the silicon oxynitride film becomes higher.

When the hydrogen concentration of the charge storage layer 4 adjacent to the tunnel insulating film 3 becomes high, hydrogen will diffuse into the tunnel insulating film 3 and the hydrogen concentration of the tunnel insulating film 3 increases. Although the charge storage layer 4 (silicon nitride film) is also formed by the ALD method, since the ammonia (NH₃) is also used as the nitriding agent, the trap amount of charge of the tunnel insulating film 3 increases.

To address such issues, the present embodiment adopts a method of reducing the hydrogen concentration in the silicon oxynitride film or the silicon nitride film while forming the silicon oxynitride film or the silicon nitride film by, for example, the ALD method. In the embodiment, the concentration of hydrogen in the silicon oxynitride film or the silicon nitride film is reduced to 1×10¹⁹ [atoms/cm³] or lower. In the embodiment, the N—H bond amount and the Si—H bond amount in the silicon oxynitride film are set to 1×10¹⁹ [pieces/cm³] or lower.

Hereinafter, a manufacturing method of the semiconductor device according to the embodiment will be described in more detail.

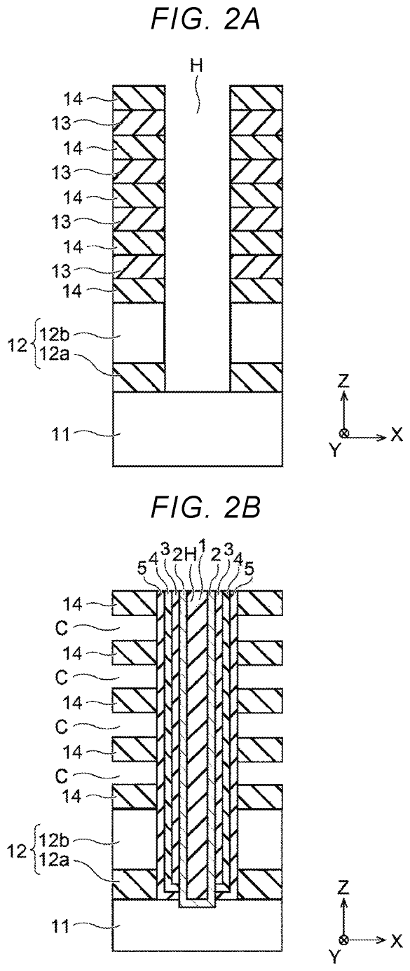

FIGS. 2A and 2B illustrate cross-sectional views of a structure to illustrate a manufacturing method of the semiconductor device according to the first embodiment.

First, as illustrated in FIG. 2A, a base layer 12 is formed on a substrate 11, and a plurality of first films 13 and a plurality of second films 14 are alternately stacked on the base layer 12. Next, the memory hole H that penetrates the base layer 12, the first film 13, and the second film 14 is formed. The memory hole H is an example of an opening. An example of the substrate 11 is a semiconductor substrate such as a silicon substrate. An example of the base layer 12 is a stacked film including an interlayer insulating film 12a on the substrate 11 and a semiconductor layer 12b on the interlayer insulating film 12a. An example of the interlayer insulating film 12a is the silicon oxide film and the silicon nitride film. An example of the semiconductor layer 12b is a polysilicon layer. The memory hole H of the embodiment is formed to penetrate the interlayer insulating film 12a and the semiconductor layer 12b. An example of the first film 13 is the silicon nitride film. An example of the second film 14 is the silicon oxide film.

The second film 14 is the insulating layer described with reference to FIG. 1. The first film 13 is a sacrificial layer used/removed in forming the wiring layer described with reference to FIG. 1. In the present embodiment, a plurality of cavities are formed between the second films 14 by removing the first film 13, and the second metal layer 8, the first metal layer 7, and the wiring layer 6 are sequentially deposited in the cavities. As a result, a plurality of wiring layers are formed in the cavities. This is referred to as a replacement process. When the replacement process is not adopted, a wiring layer such as a tungsten layer may be formed as the first film 13 in the process of FIG. 2A.

Next, as illustrated in FIG. 2B, the block insulating film 5, the charge storage layer 4, the tunnel insulating film 3, and the semiconductor channel layer 2 are sequentially formed on the side walls of the base layer 12, the first film 13, and the second film 14 in the memory hole H, and the remaining memory hole H is filled with the core insulating film 1. Next, a slit groove (not illustrated) is formed in the first film 13 and the second film 14, and the first film 13 is removed with a chemical solution such as phosphoric acid supplied via the groove. As a result, as illustrated in FIG. 2B, a plurality of cavities C are formed between the second films 14.

Specifically, the block insulating film 5, the charge storage layer 4, the tunnel insulating film 3, the semiconductor channel layer 2, and the core insulating film 1 are formed as follows. First, the block insulating film 5, the charge storage layer 4, and the tunnel insulating film 3 are sequentially formed on the side surfaces of the base layer 12, the first film 13, and the second film 14 in the memory hole H. Next, the block insulating film 5, the charge storage layer 4, and the tunnel insulating film 3 are removed by etching from a bottom part of the memory hole H. Accordingly, the substrate 11 is exposed in the memory hole H. Next, the semiconductor channel layer 2 and the core insulating film 1 are sequentially formed in the memory hole H.

The semiconductor channel layer 2 is, for example, the polysilicon layer. In order to reduce the surface roughness of the semiconductor channel layer 2, an amorphous silicon layer for forming the semiconductor channel layer 2 is formed at a low temperature of about 500° C., and the amorphous silicon layer may be heat-treated at 800° C. or higher. As a result, the amorphous silicon layer is crystallized, and the polysilicon layer having small surface roughness is formed.

Thereafter, the second metal layer 8, the first metal layer 7, and the wiring layer 6 are sequentially formed in the cavity C (refer to FIG. 1). As a result, a plurality of wiring layers are formed in the cavity C. The wiring layer 6 is formed by, for example, a chemical vapor deposition (CVD) method or the ALD method. As a result, the semiconductor device in FIG. 1 is manufactured.

The first film 13 and the second film 14 of the embodiment are stacked in such a manner that the second film 14 is first formed on the base layer 12, and when another type of three-dimensional flash memory is adopted, the first film 13 and the second film 14 may be stacked in such a manner that the first film 13 is first formed on the base layer 12. In this case, the configuration of the base layer 12 may be different from the present method. When the first film 13 and the second film 14 are directly formed on the substrate 11, the base layer 12 is not necessary.

Next, a manufacturing method of the silicon nitride film or the silicon oxynitride film according to the embodiment will be described.

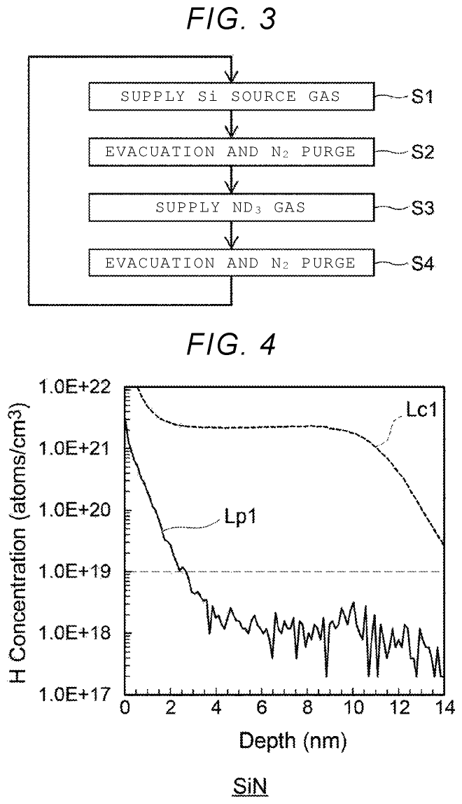

FIG. 3 is a flowchart illustrating a manufacturing method of the silicon nitride film according to the first embodiment. FIG. 3 illustrates a method of forming the silicon nitride film of the charge storage layer 4. Hereinafter, the silicon nitride film is also referred to as the SiN film.

In the embodiment, steps S1, S2, S3, and S4 are sequentially performed as a process of one cycle. This process is repeated for a plurality of cycles until the SiN film becomes a predetermined film thickness.

Specifically, the substrate 11 is housed in an ALD apparatus, and first, a Si source gas is supplied to the substrate 11 (step S1). Next, after performing evacuation and N₂ purge of the ALD apparatus (step S2), a nitriding gas is supplied to the substrate 11 (step S3). Next, after performing the evacuation and the N₂ purge of the ALD apparatus (step S4), the process returns to step S1. In the embodiment, the SiN film is formed by repeating this cycle a plurality of times. The Si source gas and the nitriding gas are examples of a first gas and a second gas, respectively. In the embodiment, a desorbing agent reacting with impurities in the Si source gas and desorbing the impurities is not used.

The Si source gas is a gas containing silicon and at least one kind of first element. Examples of the Si source gas are hexachlorodisilane (HCD; Si₂Cl₆), tetrachlorosilane (TCS; SiCl₄), and octachlorotrisilane (OCTS; Si₃Cl₈). The Si source gas of the present embodiment is HCD, and the first element in this case is chlorine (Cl). The Si source gas contains almost no light hydrogen “¹H”.

The nitriding gas is a gas containing nitrogen and deuterium. An example of the nitriding gas is ND₃. Here, D is deuterium and can also be represented as “²H” in comparison to light hydrogen “¹H” (protium). Hereinafter, for simplicity, light hydrogen is represented as H, and deuterium is represented as D. When “hydrogen” without any accompanying modifier is mentioned in the specification, then such usage is intended to reference light hydrogen H. In the present embodiment, NH₃ (ammonia) containing hydrogen H is not used as the nitriding gas or as the nitriding agent, but rather ND₃ (deuterated ammonia) containing deuterium D is used. Therefore, the nitriding gas does not contain much if any light hydrogen. That is, the SiN film will primarily be terminated with deuterium D by using ND₃ instead of using NH₃ as the nitriding gas. That is, the dangling bonds —Si* and —N* of the SiN film will be terminated with deuterium D, after which a Si-D bond and an N-D bond are formed. In this case, the concentration of hydrogen H in the SiN film can be lowered without using a desorbing agent or process. The concentration of hydrogen H in the SiN film according to the present embodiment will be described below with reference to FIG. 4.

An example of the ALD apparatus is a low-pressure batch vertical film forming furnace. In the present embodiment, the number of cycles of the above-described process is adjusted so that the SiN film becomes a desired thickness. A loop process in FIG. 3 starts from step S1, but may start from other steps as long as the SiN film can still be formed.

The SiN film of the present embodiment is formed, for example, at a temperature of 600 to 800° C. in any one of steps S1 to S4. An example of the flow conditions for ND₃ is described as follows. For example, a flow rate of ND₃ is adjusted to 1 slm to 10 slm (slm=standard liters per minute), a flow time of ND₃ is adjusted from 10 to 40 sec, and a gas partial pressure of ND₃ is adjusted from 7 to 50 Pa. For example, when the flow rate of ND₃ is 1 slm, the gas partial pressure is 7 Pa, and when the flow rate of ND₃ is 10 slm, the gas partial pressure is desirably 50 Pa. These gas flow rates may be controlled by a mass flow controller or the like.

FIG. 4 is a graph illustrating the concentration profile of hydrogen H in the SiN film. A vertical axis represents the concentration of hydrogen H. A horizontal axis represents a depth from a surface of the SiN film. A line Lc1 in FIG. 3 indicates the concentration of hydrogen H when NH₃ is used as the nitriding agent. A line Lp1 in FIG. 3 indicates the concentration of hydrogen H when ND₃ is used as the nitriding agent according to the present embodiment.

As illustrated by the line Lc1, when NH₃ is used as the nitriding agent, the concentration of hydrogen H in the SiN film is clearly higher than 1×10¹⁹ [atoms/cm³], and is at least 1×10²¹ [atoms/cm³] or higher in many places. In this case, as described above, a large number of N—H bonds exist in the charge storage layer 4, and the deterioration of the charge storage layer 4 caused by the write and erase operation cannot be prevented.

On the other hand, as illustrated by the line Lp1, when ND₃ is used as the nitriding agent, the concentration of hydrogen H contained in the SiN film is 1×10¹⁹ [atoms/cm³] or lower except for a region about 2 nm from the surface (0 nm depth). According to the present embodiment, it is possible to prevent the deterioration of the charge storage layer 4 caused by the write and erase operation by reducing the number of N—H bonds in the charge storage layer 4 and increasing the N-D bonds. The hydrogen concentration (Lp1) of the SiN film formed using ND₃ is reduced by a factor 1/100 to 1/1000 as compared with the hydrogen concentration (Lc1) of the SiN film formed using NH₃. When the concentration of hydrogen H is around 1×10¹⁹ [atoms/cm³] or lower, then it is possible that the hydrogen amount is near or below the detectable range of hydrogen H by the adopted measurement techniques. Therefore, the hydrogen concentration indicated by Lp2 might not be accurately measured at such levels and the values depicted in FIG. 4 of hydrogen concentrate represented by line LP2 may be even lower than those depicted. That is, according to the measurement methods associated with FIG. 3, it can be said that very little hydrogen if any is contained in the charge storage layer 4 beyond a depth of about 3 nm or so.

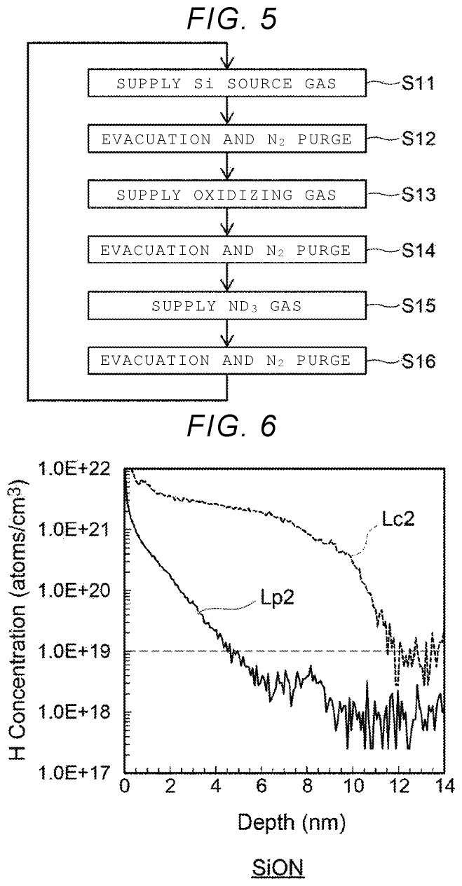

FIG. 5 is a flowchart illustrating a manufacturing method of the silicon oxynitride film according to the first embodiment. FIG. 5 shows a method of forming the silicon oxynitride film of the tunnel insulating film 3. Hereinafter, the silicon oxynitride film is also referred to as the SiON film.

In the present embodiment, steps S11 to S16 are sequentially performed as a process cycle. Then, the SiON film is formed by repeating this process cycle for a plurality of cycles.

Specifically, the substrate 11 is housed in the ALD apparatus, and first, the Si source gas is supplied to the substrate 11 (step S11). Step S11 may be the same as step S1. Next, after performing the evacuation and the N₂ purge of the ALD apparatus (step S12), an oxidizing gas (oxidant) is supplied to the substrate 11 (step S13). Next, after performing the evacuation and the N₂ purge of the ALD apparatus (step S14), the nitriding gas is supplied to the substrate 11 (step S15). Next, after performing the evacuation and the N₂ purge of the ALD apparatus (step S16), the process returns to step S11. In the embodiment, the SiON film is formed by repeating this cycle a plurality of times. The oxidizing gas is an example of a third gas. The desorbing agent is not used also in the process of forming the SiON film.

The Si source gas and the nitriding gas are the same as those in the process of forming the SiN film. The oxidizing gas is, for example, an oxygen (O₂) gas, D₂O, and O₃. Flow conditions for ND₃ may be also the same as those in the SiN film forming process. The SiN film of the embodiment is formed at a temperature of, for example, 600 to 800° C. in any one of steps S11 to S16.

An example of the ALD apparatus is a low-pressure batch vertical film forming furnace. In the embodiment, the number of cycles of the above-described process is adjusted so that the SiON film becomes a desired thickness. A loop process of FIG. 5 starts from step S11, and may start from other steps as long as the SiON film can be formed. According to the method of the embodiment, the SiON film having the nitrogen concentration of 10 to 30 at % can be formed.

FIG. 6 is a graph illustrating the concentration of hydrogen H in the SiON film. A vertical axis represents the concentration of hydrogen H. A horizontal axis represents a depth from a surface of the SiON film. A line Lc2 illustrated in FIG. 5 indicates the concentration of hydrogen H when NH₃ is used as the nitriding agent. A line Lp2 illustrated in FIG. 5 indicates the concentration of hydrogen H when ND₃ is used as the nitriding agent according to the present embodiment.

As illustrated by the line Lc2, when NH₃ is used as the nitriding agent, the concentration of hydrogen H in the SiON film is clearly higher than 1×10¹⁹ [atoms/cm³], and becomes 1×10²¹ [atoms/cm³] or higher. In this case, as described above, a large number of N—H bonds exist in the tunnel insulating film 3, and the deterioration of the tunnel insulating film 3 caused by the write and erase operation cannot be prevented.

On the other hand, as illustrated by the line Lp2, when ND₃ is used as the nitriding agent, the concentration of hydrogen H contained in the SiON film is 1×10¹⁹[atoms/cm³] or lower except about 4 nm on the surface. According to the embodiment, it is possible to prevent the deterioration of the tunnel insulating film 3 caused by the write and erase operation by reducing the number of NH bonds in the tunnel insulating film 3 and increasing the number of N-D bonds. The hydrogen concentration (Lp2) of the SiON film formed using ND₃ is reduced by a factor of 1/100 to 1/1000 as compared with the hydrogen concentration (Lc2) of the SiON film formed using NH₃. A concentration of hydrogen H is 1×10¹⁹ [atoms/cm³] or lower, at or below the reliable detectable range of hydrogen H by the measurement techniques utilized for establishing FIG. 6. Therefore, the hydrogen concentration indicated by Lp2 is not likely to be accurately measured and thus may be even lower than that depicted in FIG. 6. That is, according to FIG. 5, it can be said that hydrogen is contained in the tunnel insulating film 3 at only low concentrations, if at all, beyond a depth of about 5 nm.

The tunnel insulating film 3 may be a stacked film including the first silicon oxide film, the silicon oxynitride film, and the second silicon oxide film. In this case, when the silicon oxynitride film is formed between the first silicon oxide film and the second silicon oxide film, the method in FIG. 5 may be used.

It is desirable to reduce the number of N—H bonds in both the tunnel insulating film 3 and the charge storage layer 4 by applying both the methods of FIGS. 3 and 5. It is possible not only to control the diffusion of hydrogen H between the charge storage layer 4 and the tunnel insulation film 3, but also to prevent the deterioration of both the tunnel insulation film 3 and the charge storage layer 4.

On the other hand, the methods associated with either one of FIGS. 3 and 5 may be applied to reduce the number of N—H bonds one or the other of the tunnel insulating film 3 and the charge storage layer 4. In such a case, hydrogen H will diffuse to some extent between the charge storage layer 4 and the tunnel insulating film 3, and the deterioration of the tunnel insulating film 3 or the charge storage layer 4 can be prevented to fullest possible extent.

The SiN film and the SiON film formed by using ammonia (NH³) as the nitriding agent have a high hydrogen concentration. In order to desorb hydrogen from the SiN film and the SiON film, it is conceivable to perform a heating treatment, such as a rapid thermal anneal (RTA) method. However, even though such SiN films and SiON films are heat-treated for about 3 minutes in an atmosphere of 800° C. or higher (for example, about 1100° C.) by using the RTA method, the hydrogen concentration thereof will be lowered by only about 30%.

On the other hand, when the SiN film and the SiON film are formed by using ND₃ as the nitriding agent as in the present embodiment, as illustrated in FIGS. 4 and 6, the hydrogen concentration (Lp1, Lp2) of the SiN film and the SiON film can be reduced by a factor of 1/100 to 1/1000 as compared with the hydrogen concentration (Lc1, Lc2) of the SiN film and the SiON film formed using ammonia (NH³). According to the present embodiment, the manufacturing processing is performed at a maximum temperature of 600 to 800° C. and a high-temperature heat treatment, such as a RTA method, is not required. Therefore, the characteristics of other semiconductor elements formed on the same substrate as the memory cell array will be less affected by heating during manufacturing.

### Second Embodiment

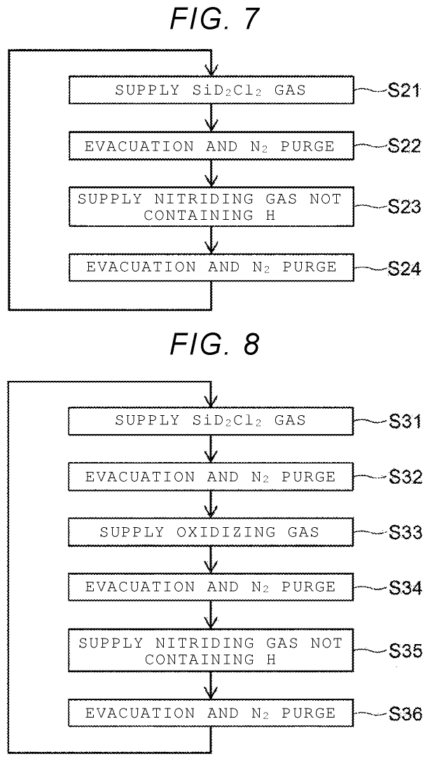

FIG. 7 is a flowchart illustrating a manufacturing method of a silicon nitride film in a semiconductor device according to a second embodiment. FIG. 7 shows a method of forming the SiN film of the charge storage layer 4. In the second embodiment, a gas containing deuterium D is used as the Si source gas. A gas not that does not light hydrogen H is used as the nitriding gas.

In the second embodiment, steps S21 to S24 are sequentially performed as a process cycle. This process cycle is repeated for a plurality of cycles until the SiN film reaches a predetermined thickness.

First, SiD₂Cl₂ gas is supplied as the Si source gas to the substrate 11 (step S21). Next, after performing the evacuation and the N₂ purge of the ALD apparatus (step S22), the nitriding gas (nitriding agent) not containing light hydrogen H is supplied to the substrate 11 (step S23). Next, after performing the evacuation and the N₂ purge of the ALD apparatus (step S24), the process returns to step S21. In the embodiment, the SiN film is formed by repeating this cycle a plurality of times. The SiD₂Cl₂ gas and the nitriding gas are examples of the first gas and the second gas, respectively. Even in the embodiment, the desorbing agent that desorbs impurities is not used. In any one of steps S21 to S24, for example, the process is performed at a temperature of 600 to 800° C.

The SiD₂Cl₂ gas contains deuterium D but almost does not contain light hydrogen H. In this manner, the SiN film is terminated with deuterium D by using the SiD₂Cl₂ gas that almost does not contain hydrogen H but contains deuterium D. In this case, the concentration of hydrogen H in the SiN film can be lowered without using a desorbing agent.

The nitriding gas is a gas that does not contain light hydrogen H but does contain nitrogen N. For that reason, NH₃ is inappropriate as the nitriding gas in this embodiment. Examples of a nitriding gas that does not contain light hydrogen H are NBr₃ gas, nitric oxide (NO) gas or nitrous oxide (N₂O) gas in addition to ND₃. By using such a nitriding gas, the concentration of hydrogen H in the SiN film can be kept low without replacing deuterium D in the SiN film with light hydrogen H.

FIG. 8 is a flowchart illustrating the manufacturing method of a silicon oxynitride film in the semiconductor device according to the second embodiment. FIG. 8 shows a method of forming the SiON film of the tunnel insulating film 3. In the second embodiment, the gas containing deuterium (D) is used as the Si source gas. A gas not containing light hydrogen H is used as the nitriding gas.

In the second embodiment, steps S31 to S36 are sequentially performed as a process cycle. The process cycle is repeated for a plurality of cycles until the SiON film reaches a predetermined film thickness.

First, the SiD₂Cl₂ gas is supplied as the Si source gas to the substrate 11 (step S31). Next, after performing the evacuation and the N₂ purge of the ALD apparatus (step S32), the oxidizing gas (for example, an oxygen (O₂) gas, D₂O, and O₃) is supplied to the substrate 11 (step S33). Next, after performing the evacuation and the N₂ purge of the ALD apparatus (step S34), the nitriding gas (nitriding agent) not containing the light hydrogen H is supplied (step S35). Next, after performing the evacuation and the N₂ purge of the ALD apparatus (step S36), the process returns to step S31. In the second embodiment, the SiON film is formed by repeating this cycle a plurality of times. The SiD₂Cl₂ gas and the nitriding gas are examples of the first gas and the second gas, respectively. Even in the embodiment, the desorbing agent that desorbs impurities is not used. In any one of steps S31 to S36, for example, the process is performed at a temperature of 600 to 800° C.

The SiD₂Cl₂ gas contains deuterium D but almost does not contain light hydrogen H. In this manner, the SiN film is terminated with deuterium D by using the SiD₂Cl₂ gas that almost does not contain hydrogen H but contains deuterium D. In this case, the concentration of hydrogen H in the SiN film can be lowered without using the desorbing agent.

The nitriding gas is a gas that does not contain light hydrogen H but contains nitrogen N. That is, in the present embodiment, NH₃ is inappropriate as the nitriding gas. Examples of a nitriding gas that does not contain light hydrogen H are NBr₃, NO, and N₂O in addition to ND₃. By using such a nitriding gas, the concentration of hydrogen H in the SiN film can be kept low without replacing deuterium D in the SiN film with light hydrogen H.

As in the second embodiment, deuterium (D) may be contained in the Si source gas. Even in this case, the SiN film is terminated with deuterium (D), and the deterioration of the charge storage layer 4 and the tunnel insulating film 3 caused by the write and erase operation can be reduced in the same manner as the first embodiment.

Even in the second embodiment, the hydrogen concentration of the SiN film and the SiON film can be reduced by a factor of 1/100 to 1/1000 as compared with the hydrogen concentration of the SiN film and the SiON film using ammonia (NH₃). Even in the second embodiment, the formation is performed at a temperature of 600 to 800° C. and a high-temperature heating treatment such as the RTA method is not required. The second embodiment can also achieve the same effect as that of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a stacked body including a plurality of first films and a plurality of second films;
forming, in the stacked body, an opening that extends in a thickness direction of the stacked body; and
forming a first insulating film, a charge storage layer, a second insulating film, and a semiconductor layer on a side wall of the opening, wherein
the charge storage layer includes a silicon nitride film,
the second insulating film includes a silicon oxynitride film, and
the silicon nitride film is formed by using a first gas containing silicon and a second gas containing nitrogen and deuterium.

2. The method according to claim 1, wherein the second gas comprises deuterated ammonia (ND₃) gas.

3. The method according to claim 1, wherein the first gas comprises SiD₂Cl₂ and the second gas comprises at least one of deuterated ammonia (ND₃), NBr₃, nitric oxide, and nitrous oxide.

4. The method according to claim 1, wherein an amount of deuterium in the second gas is greater than an amount of light hydrogen in the second gas.

5. The method according to claim 1, wherein the silicon nitride film is formed in an atmosphere of 600° C. to 800° C.

6. The method according to claim 1, wherein the silicon oxynitride film is formed using the first gas, the second gas, and a third gas containing oxygen.

7. The method according to claim 6, wherein the second gas contains deuterated ammonia (ND₃).

8. The method according to claim 6, wherein the first gas contains SiD₂Cl₂ and the second gas contains at least one of deuterated ammonia (ND₃), nitrogen tribromide (NBr₃), nitric oxide, and nitrous oxide.

9. The method according to claim 6, wherein an amount of deuterium in the second gas is greater than an amount of light hydrogen in the second gas.

10. The method according to claim 6, wherein each of the silicon nitride film and the silicon oxynitride film is formed in an atmosphere of 600° C. to 800° C.

11. A method of manufacturing a semiconductor device, comprising:
forming a stacked body including a plurality of first films and a plurality of second films that are alternately stacked on each other;
forming an opening in the stacked body that extends in a thickness direction of the stacked body; and
forming a first insulating film, a charge storage layer, a second insulating film, and a semiconductor layer on a side wall of the stacked body in the opening, wherein
the charge storage layer includes a silicon nitride film,
the second insulating film includes a silicon oxynitride film, and
the silicon oxynitride film is formed by using a first gas containing silicon, a second gas containing nitrogen and deuterium, and a third gas containing oxygen.

12. The method according to claim 11, wherein the second gas contains deuterated ammonia (ND₃).

13. The method according to claim 11, wherein the first gas contains SiD₂Cl₂ and the second gas contains at least one of deuterated ammonia (ND₃), nitrogen tribromide (NBr₃) gas, nitric oxide, and nitrous oxide.

14. The method according to claim 11, wherein an amount of deuterium in the second gas is greater than an amount of light hydrogen in the second gas.

15. The method according to claim 11, wherein the silicon oxynitride film is formed in an atmosphere of 600° C. to 800° C.

16. A semiconductor device comprising:
a stacked body including a plurality of first films and a plurality of second films that are alternately provided, the stacked body including an opening extending in a thickness direction;
a first insulating film on a side wall of the stacked body in the opening;
a charge storage layer on a surface of the first insulating film in the opening;
a second insulating film on a surface of the charge storage layer in the opening; and
a semiconductor layer on a surface of the second insulating film in the opening, wherein
the charge storage layer includes a silicon nitride film,
the second insulating film includes a silicon oxynitride film, and
a hydrogen concentration of the silicon nitride film is 1.0×10¹⁹ atoms/cm³ or less in at least at a part of the silicon nitride film in a depth direction from a center of the opening towards an outside of the opening.

17. The semiconductor device according to claim 16, wherein the part of the silicon nitride film is more than a half of the silicon nitride film in the depth direction.

18. The semiconductor device according to claim 16, wherein hydrogen concentration of the silicon oxynitride film is 1.0×10¹⁹ atoms/cm³ or less at least at a part of the silicon oxynitride film in the depth direction.

19. The semiconductor device according to claim 18, wherein the part of the silicon oxynitride film is more than a half of the silicon oxynitride film in the depth direction.

20. The semiconductor device according to claim 18, wherein each of the silicon nitride film and the silicon oxynitride film contains deuterium.
